(19) United States
(12) Patent Application Publication
(10) Pub. No.: US 2019/0129301 A1
(43) Pub. Date: May 2, 2019

(54) RESIST COMPOSITIONS

(71) Applicant: ASML NETHERLANDS B.V., Veldhoven (NL)

(72) Inventors: Willem-Pieter VOORTHUIJZEN, 's-Hertogenbosch (NL); Marie-Claire VAN LARE, Utrecht (NL); Sander Frederik WUISTER, Eindhoven (NL)

(73) Assignee: ASML NETHERLANDS B.V., Veldhoven (NL)

(21) Appl. No.: 16/301,465

(22) PCT Filed: Apr. 21, 2017
(86) PCT No.: PCT/EP2017/059475

§ 371 Date: Nov. 14, 2018

(30) Foreign Application Priority Data
May 19, 2016 (EP) 16170399.6

(51) Int. Cl. G03F 7/004; G03F 7/039; G03F 7/038; G03F 7/20; G03F 7/32; G03F 7/16; H01L 21/027

(52) U.S. Cl. CPC G03F 7/0044; G03F 7/039; G03F 7/038; H01L 21/0274; G03F 7/2037; G03F 7/32; G03F 7/16; G03F 7/2004

(57) ABSTRACT

A resist composition having a) metal-containing nanoparticles and/or nanoclusters, and b) ligands and or organic linkers, wherein one or both of a) or b) are multivalent. A resist composition wherein: the resist composition is a negative resist and the nanoparticles and/or nanoclusters cluster upon crosslinking of the ligands and/or organic linkers following exposure to electromagnetic radiation or an electron beam; or the resist composition is a negative resist and the ligands and/or organic linkers are crosslinked and the crosslinking bonds are broken upon exposure to electromagnetic radiation or an electron beam allowing the nanoparticles and/or nanoclusters to cluster together; or the resist composition is a positive resist and the ligands and/or organic linkers are crosslinked and the crosslinking bonds are broken upon exposure to electromagnetic radiation or an electron beam.

### CROSS-REFERENCE TO RELATED APPLICATIONS

This application claims priority of EP application 16170399.6 which was filed on May 19, 2016 and which is incorporated herein in its entirety by reference.

### FIELD

The present invention relates to resist compositions for use in lithography and a method of producing a semiconductor using such resist compositions. In particular, the present invention relates to resist compositions for use in EUV lithography.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

Known resists suitable for use with lithography are referred to as chemically amplified resists (CAR) and are based on polymers. Upon expose to electromagnetic radiation or an electron beam, the polymers in the CAR absorb photons or interact with electrons, and secondary electrons are generated. The generation of secondary electrons is how a high-energy photon or electron loses most of its energy. The secondary electrons in the resist diffuse and may generate further secondary electrons with lower energies until the energy of the secondary electrons is lower than that required to break bonds in the CAR or result in ionisation. The electrons generated excite photo-acid generators (PAG) which subsequently decompose and can catalyse a deblocking reaction, which leads to a change in the solubility of the CAR. The PAGs can diffuse within the resist and this contributes to blurring. Known CARs rely on the absorption of photons by carbon atoms. However, carbon has a low absorption cross-section in the EUV spectral range. As a consequence of this, known CARs are relatively transparent to EUV photons so high doses of EUV radiation are required and this in turn requires high power EUV sources. In future, with the advent of Beyond EUV (BEUV) systems, the absorption of BEUV photons by carbon atoms is even lower and so even higher doses are likely to be required.

A further drawback with known resists is the substantial chemical noise which results from the mechanism of action of CARs. The chemical noise causes roughness and limits the size of the features which can be realised. In particular, the noise is inherent in the mechanism of action of CARs since the mechanism is based on PAGs which can diffuse through the resist before reacting. As such, the ultimate location where the reaction causing a change in the solubility of the resist in a developer takes place is not only limited to the area on which the EUV photons are incident on the resist. In addition, with CAR systems, pattern collapse becomes an issue at low critical dimensions as a result of the blur caused by the nature of the CAR system. Furthermore, with the size of the features desired to be produced shrinking, it is predicted that at 7 nm, CAR-type resists would require a dose of 50 mJ/cm², which is considered to be a high dose, and hence alternative resist platforms are required. In cases where high doses are required, it is necessary for the resist to be exposed to the electromagnetic radiation source for a longer period of time. As such, the number of chips which can be produced by a single machine in a given time period is reduced.

Alternative resist systems for use with lithography, in particular EUV lithography, comprising metal oxide nanoparticles have been investigated to try to address the issues with CARs. These alternative resist systems comprise metal oxide nanoparticles which are prevented from clustering together by a ligand shell. Upon EUV exposure, photons are absorbed by the nanoparticles and this leads to the generation of secondary electrons. The electrons break the bonds between the ligands and the nanoparticles. This allows the nanoparticles to cluster together and hence changes the solubility of the resist. The metal oxide nanoparticles have larger EUV absorption cross-sections than carbon atoms in CAR and thus there is a greater likelihood of EUV photons being absorbed. Therefore, a less intense beam requiring less power or a shorter exposure to the EUV photons is required. Furthermore, the different conversion mechanism has potentially lower chemical noise than CAR resist systems. Even though the metal oxide nanoparticle systems have greater EUV absorption than CAR systems, there remains a trade-off between efficiency and blur; in systems with high conversion efficiency, i.e. a high number of electrons produced by the incident EUV photons, a single photon may generate a number of secondary electrons. As with CAR systems, these electrons may travel through the system before causing chemical reactions leading to the removal of ligands, and this diffusion of electrons results in high blur. The radius of the metal oxide nanoparticles is typically around 0.3 to 0.4 nm, whereas the electrons created by the absorption of the EUV photons can diffuse by a few nanometers. As such, electrons may diffuse towards particles which neighbour the particle which absorbed the EUV photon, and may break the bond between such neighbouring particle and a ligand bonded to such neighbouring particle. This can lead to blur and hence large local critical dimension uniformity (LCDU) values, both of which are undesirable.

One such metal oxide based system is discussed in EP2988172, which uses a solution comprising water, metal suboxide cations, polyatomic inorganic anions and monovalent ligands comprising peroxide groups. The molar concentration of ligands to metal suboxide cations is at least about 2, and the resist composition is stable with respect to phase separation for at least about two hours without additional mixing. It is suggested that upon absorption of radiation, the peroxide functional groups are fragmented and the composition condenses via the formation of bridging metal-oxygen bonds. However, although the use of metal oxide particles increases the absorption cross-section compared with the absorption cross section of carbon in CAR systems, the high conversion efficiency means that many secondary electrons are created. In EP2988172, the secondary electrons are free to diffuse through the system and fragment the peroxide groups. Thus, there is a high degree of blur and large LCDU (local critical dimension uniformity) values, which are both undesirable.

It is preferable for the LCDU values to remain within limits of 15% and thus lower efficiency systems are required to avoid the problems associated with known metal oxide nanoparticle systems. However, this requires a higher dose of EUV to be used and hence the throughput of the process is reduced.

Whilst the present application generally refers to EUV lithography throughout, the invention is not limited to solely EUV lithography and it is appreciated that the subject matter of the present invention may be used in resists for photolithography using electromagnetic radiation with a frequency above or below that of EUV, or in any other type of lithography, such as electron beam lithography.

### SUMMARY

The present invention has been made in consideration of the aforementioned problems with known resists, in particular with EUV resists. The present invention allows improved absorption of electromagnetic radiation, such as EUV, whilst also controlling the amount of blur. Whilst the absorption cross-section of resists can be improved by moving away from CARs to resists comprising metal oxide nanoparticles, the increased absorption cross-section can result in blur caused by the increased number of secondary electrons generated.

According to a first aspect of the present invention, there is provided a resist composition comprising a) metal-containing nanoparticles and/or nanoclusters, and b) ligands and/or organic linkers, wherein one or both of components a) or b) are multivalent. Preferably, both components a) and b) are multivalent. The metal-containing nanoparticles and/or nanoclusters may contain covalently bonded host- and/or guest-groups that can bind multivalently or on which ligands and/or organic linkers are assembled which bind in multivalent fashion. As will be explained in more detail below, using nanoparticles/nanoclusters and/or ligands/organic linkers which are multivalent results in a greater degree of control over any secondary electrons generated and thereby reduces blur. An organic chain may be attached to a MO cluster with host, guest, or both host and guest end groups, and these end groups may multivalently bond with host and/or guest end groups of molecules attached to other MO clusters or with other MO clusters directly. One ligand and/or organic linker may have multiple bonds with one nanoparticle and/or nanocluster. One ligand and/or organic linker may have multiple bonds with at least one other ligand and/or organic linker. One ligand or organic linker may have multiple bonds with at least one nanoparticle or nanocluster and at least one other ligand or organic linker. Organic linkers with either host or guest groups may be incorporated in the synthesis of MO-clusters. In such an embodiment MO-clusters with multiple host groups will bind multivalently with multiple guest groups. Organic carbohydrate chains may be connected to either metal or oxide atoms. The formation or breaking of one of these multivalent bonds alters the likelihood of a further multivalent bond forming or breaking respectively.

The resist composition may be a negative resist or a positive resist. Where the resist composition is a negative resist, the nanoparticles/nanoclusters cluster upon crosslinking of the ligands and/or organic linkers, and the nanoparticles and/or nanoclusters. The crosslinking is preferably caused by exposure to electromagnetic radiation or an electron beam. Preferably the crosslinking reduces the solubility of the resist composition in a developer. In an alternative negative resist composition, the breaking of the crosslinked bonds by exposure to electromagnetic radiation or an electron beam allows the nanoparticles/nanoclusters to cluster together. The solubility in a developer of the nanoparticles/nanoclusters which have clustered together is preferably reduced. Where the resist composition is a positive resist, the ligands/organic linkers are preferably initially crosslinked and the crosslinking bonds are broken upon exposure to electromagnetic radiation or an electron beam. Preferably, the breaking of the crosslinking bonds makes the positive resist composition more soluble in a developer. Alternatively or additionally a developer solution for use in a positive resist may contain a high concentration of monovalent ligands/organic linkers to force ligand/organic linker desorption on nanoparticles/nanoclusters or to induce competition between mono- and multivalent hosts and/or guests.

The metal-containing nanoparticles and/or nanoclusters may be metal oxide nanoparticles or nanoclusters. The metal oxide nanoparticles or nanoclusters may comprise any suitable metal. The nanoparticles may be metal oxide clusters. The metal in the metal oxide nanoparticles or nanoclusters may comprise one or more alkali metals, alkali earth metals, transition metals, lanthanides, actinides, or post-transition metals. Post-transition metals are metals which are situated in the p-block of the periodic table. Preferably the metal is chosen from tin or hafnium, but many other metal oxides with a high EUV absorption cross-section may be used. Preferably, the metal oxide is SnO₂ or HfO₂. Metals generally have higher EUV absorption cross sections compared with carbon and so resists which comprise metals are relatively less transparent to EUV radiation than resists which rely on carbon to absorb the electromagnetic radiation. Tin and hafnium in particular exhibit good absorption of EUV radiation and electron beams, and show etch resistance.

The metal-oxide nanoparticles/nanoclusters may comprise one or more metal oxides. Additional compounds may be present in the nanoparticles/nanoclusters. The properties of the nanoparticles/nanoclusters may be tuned to provide optimized performance depending on the exact nature of the lithography for which the resist is being utilized.

The metal-containing nanoparticles and/or nanoclusters may be of any suitable size. Preferably, the total lateral dimension of the nanoparticles and/or nanoclusters is from about 0.1 nm to about 10 nm, more preferably from about 0.5 nm to about 5 nm, and most preferably about 0.7 nm to about 1 nm.

Preferably, the height of the nanoparticles and/or nanoclusters is from about 0.1 nm to about 10 nm, more preferably from about 0.5 nm to about 5 nm, and most preferably about 2 nm. It is necessary for the nanoparticles and/or nanoclusters to be small in order to minimize blur. However, if the nanoparticles and/or nanoclusters are too small, there are a greater number of bonds to form or break, which requires a higher dose and therefore throughput is reduced. It has been surprisingly found that nanoparticles and/or nanoclusters of the size indicated herein offer the best balance between minimization of blur and the dose required.

The resist composition may comprise first nanoparticles and/or nanoclusters having a first composition and second nanoparticles and/or nanoclusters having a second composition. It will be appreciated that further nanoparticles and/or nanoclusters having yet further compositions may also be included in the resist composition. It may be advantageous to have more than one type of nanoparticle and/or nanocluster in the composition in order to tune the performance of the resist to the particular task for which it is being utilized.

The resist composition may comprise one or more different ligands and/or organic linkers. A ligand may self-assemble on the surface of a nanoparticle/nanocluster. An organic linker is a molecule which is able to bond to a nanoparticle/nanocluster and link the nanoparticle/nanocluster to a second nanoparticle/nanocluster directly or via a second organic linker. A ligand may be an organic linker, and vice versa.

The metal-containing nanoparticles and/or nanoclusters may comprise a plurality of guest sites or host sites. The metal-containing nanoparticles and/or nanoclusters may comprise both host and guest sites. The ligands and/or organic linkers may comprise a plurality of host sites or guest sites. The ligands and/or organic linkers may comprise both host and guest sites. Any suitable combination of host and guest sites may be used.

The resist composition is preferably suitable for use with EUV. Preferably, the resist composition is also suitable for use with photons having a higher or lower frequency than EUV. The resist composition may also be suitable for use with electron-beam lithography. The resist composition may be a photoresist composition.

Preferably, the solubility of the resist in a developer is altered on exposure to electromagnetic radiation, such as EUV, or an electron beam. In case of a negative resist composition, the solubility in a developer of the area or areas of the resist composition exposed to the electromagnetic radiation or electron beam may be reduced relative to the solubility of the unexposed area or areas of the resist composition. In the case of a positive resist composition, the solubility in a developer of the area or areas of the resist composition exposed to the electromagnetic radiation or electron beam may be increased relative to the solubility of the unexposed area or areas of the resist composition.

In a first embodiment of the present invention, the metal-containing nanoparticles and/or nanoclusters, preferably metal oxide nanoparticles and/or nanoclusters, may be surrounded by a plurality of multivalent ligands and/or organic linkers. The multivalent ligands and/or organic linkers may form a shell around the nanoparticles and/or nanoclusters. Upon exposure to electromagnetic radiation, such as EUV, or an electron beam, a guest site of a first nanoparticle/nanocluster or a nanoparticle/nanocluster with a guest site connected by an organic linker or a ligand surrounding said first nanoparticle/nanocluster may form a bond with a host site of a second nanoparticle/nanocluster or a ligand/organic linker surrounding said second nanoparticle/nanocluster or nanoparticle/nanocluster with a host group connected by an organic linker. Preferably, the formation of such a bond makes it more energetically favourable to form bonds between the first and/or second nanoparticles/nanoclusters, or ligands/organic linkers surrounding the first and/or second nanoparticles/nanoclusters, with other nanoparticles/nanoclusters and/or ligands/organic linkers. Since the ligands/organic linkers and nanoparticles/nanoclusters and nanoparticles/nanoclusters with an organic linker with a host or guest group are multivalent, the formation of a bond between two nanoparticles/nanoclusters via a multivalent ligand/organic linker makes it energetically more favourable for other ligands/organic linkers to form bonds with such nanoparticles/nanoclusters. Thus, it is more likely that the secondary electrons generated by the absorption of a photon by a nanoparticle/nanocluster lead to bond formation between the nanoparticle/nanocluster which absorbed the photon and another nanoparticle/nanocluster, rather than the secondary electrons generated by one nanoparticle/nanocluster diffusing away and forming or breaking a bond between other nanoparticles/nanoclusters. Consequently, it is less likely for the secondary electrons to diffuse through the resist and cause bond formation between nanoparticles/nanoclusters which have not themselves been exposed to electromagnetic radiation, thereby causing blurring. It will be understood that reference to bonds between nanoparticles/nanoclusters do not have to be direct bonds between nanoparticles/nanoclusters, but may be formed via one or more ligands and/or organic linkers between the nanoparticles/nanoclusters. However, forming multivalent bonds using MO-clusters/particles with multiple host and or guest groups is most desirable and thermodynamically favourable as in such an embodiment MO-clusters/particles are positioned with respect to each other which might result in more localized clustering reactions between MO-clusters/particles. It is also expected that such ‘deterministic positioning’ in itself can reduce blur and LWR and LER. It is also possible for the host-guest bonds to be between a nanoparticle/nanocluster and a ligand/organic linker, such that a ligand/organic linker can bridge two nanoparticles/nanoclusters.

Preferably, the area or areas of the resist where the ligands/organic linkers are bonded to other ligands/organic linkers have a different solubility in a developer than the area or areas where the ligands/organic linkers are not bonded to other ligands/organic linkers. Preferably, the area or areas of the resist where the ligands/organic linkers have become bonded to other ligands/organic linkers has a lower solubility in developer than the area or areas where the ligands/organic linkers are not bonded to other ligands/organic linkers. Preferably, the formation of guest-host bonds between the ligands/organic linkers causes the nanoparticles/nanoclusters to cluster thereby reducing the solubility of the area exposed to the electromagnetic radiation or the electron beam in a developer. It will be appreciated that the bonds do not necessarily have to be between ligands/organic linkers, but may also be between nanoparticles/nanoclusters and ligands/organic linkers. For example, in this way nanoparticle-ligand-nanoparticle bonds or nanocluster-organic linker-nanocluster bonds may be formed. It could be envisioned formation of secondary electrons causes random scission reactions by either secondary electrons or radicals formed which might result in direct clustering of nanoparticles/nanoclusters by disintegration of any carbohydrate or other organic component.

In a second embodiment of the present invention, the metal-containing nanoparticles and/or nanoclusters, preferably metal oxide nanoparticles and/or nanoclusters, may be surrounded by a plurality of multivalent ligands and/or organic linkers. The multivalent ligands/organic linkers may form a shell around the metal-containing nanoparticles/nanoclusters. Prior to exposure to electromagnetic radiation, such as EUV, there are bonds between the guest sites on ligands/organic linkers and the host sites on other ligands/organic linkers. Thus, the nanoparticles/nanoclusters and/or ligands/organic linkers may be crosslinked. The bonds may also be between host sites on the nanoparticles/nanoclusters and guest sites on the ligands/organic linkers, or vice versa. In this way, there is a matrix of ligands/organic linkers and nanoparticles/nanoclusters held together with host-guest bonds. Upon expose to electromagnetic radiation, such as EUV, or an electron beam, the guest-host bonds are broken and the breaking of said guest-host bonds makes it more energetically more favourable to break bonds between ligands/organic linkers surrounding the metal-containing nanoparticles/nanoclusters associated with the ligands/organic linkers whose guest-host bonds have been broken than other nanoparticles/nanoclusters whose associated ligands/organic linkers have not had their guest-host bonds broken. The breaking of the bonds between ligands and/or organic linkers may allow the nanoparticles/nanoclusters to cluster together.

Preferably, the breakage of bonds between the guest and host sites alters the solubility in developer of the area or areas of the resist where the breakage occurs. The solubility may increase or decrease. Preferably, the matrix system is soluble in a developer.

Where the resist is a positive resist, the developer may contain monovalent ligands/organic linkers with guest and/or host sites which compete with the multivalent ligands/organic linkers. The monovalent ligands/organic linkers may bind to the multivalent ligands/organic linkers and thereby separate the nanoparticles/nanoclusters. The use of multivalent ligands/organic linkers in the second embodiment of the present invention controls the secondary electrons generated by irradiation. This allows the amount of blur to be reduced whilst allowing a high number of chips to be produced by a single machine in a given period of time.

The host groups forming the host sites may comprises any suitable group. For example, the host group may be a primary ammonium group, a secondary ammonium group, a tertiary ammonium group, a quaternary ammonium group, an amine oxide, a carbocation, or small DNA bases, or a peptide. The guest groups forming the guest sites may comprise any suitable group. For example, the guest group may comprise small DNA bases, peptides, carboxylic acids or the charged surface areas of nanoparticles/nanoclusters, such as SnOₓ or HfOₓ clusters.

The ligand may comprise a linker portion. The linker portion may be organic. The linker portion may comprise poly(ethylene imine), poly(ethylene glycol), poly(methylene oxide), poly(acrylamide), poly(vinyl alcohol), poly(acrylic acid), or any carbohydrate chain. Carbohydrate chains may be equipped with atoms with high EUV absorption cross-section such as nitrogen or oxygen. The linker portion may form the backbone of the ligand. The linker portion may connect the groups comprising the host and/or guest sites on a ligand. The linker portion may be selected in order to make the resist composition crosslinked prior to irradiation and then for the crosslinking bonds to be broken following irradiation. Alternatively, the linker portion may be chosen in order to make the resist composition not crosslinked prior to irradiation and to become crosslinked following irradiation.

The ligand and/or organic linker may comprise one or more cleavable groups. The one or more cleavable groups may be any suitable group. The cleavable groups may be thermocleavable. The thermocleavable groups may be, for example, esterquats, carbonate esters, supramolecular donor-acceptor systems, such as peptide bonds. The thermocleavable bonds may be based on carbamates or diels-alder reactions. The one or more cleavable groups may be cleavable or coupled by EUV, such as azulenes, spiropyrans, azobenzenes, or viologens. The cleavable groups may be based on thiol-ene chemistry, cis-trans chemistry, keto-enol tautomerism, supramolecular donor-acceptor systems, such as peptide bonds, and photolabile groups. The one or more cleavable groups may also be cleavable by other means, such as by acids, bases, reduction or oxidation, and may comprise amides, diselenides, disulfides, acetals, trithiocarbonates, carbonates, ketals, esters, ortho esters, imines, hydrazones, hemi acetal esters, or olefins. It will be appreciated that this is not an exhaustive list of possible cleavable groups and the skilled person would understand that other groups may be suitable depending on the circumstances in which the resist composition is used. The ligand and/or organic linker may comprise one or more curable groups. A curable group is a group which may become cross-linked upon exposure to suitable radiation, such as EUV or an electron beam. Curing may also be induced by chemical or thermal means.

The resist composition may additionally comprise any suitable solvent.

According to a third embodiment of the present invention, there is provided a method of producing a semiconductor, the method comprising; applying to a semiconductor substrate a resist composition comprising: a) metal-containing nanoparticles and/or nanoclusters, and b) ligands and/or organic linkers, wherein one or both of a) or b) are multivalent; exposing the resist to electromagnetic radiation or an electron beam; and developing the resist.

The resist composition used in the method of the third aspect of the present invention may be any one of the resist compositions disclosed herein.

The electromagnetic radiation may be EUV. The electromagnetic radiation may have a frequency greater or less than that of EUV.

The method of the third aspect of the present invention may also comprise a baking of the semiconductor substrate. Preferably, baking takes place after the electromagnetic radiation or electron beam exposure step.

Preferably, the thickness of the resist composition is such that the absorption in the resist layer is from about 10% to about 50%, from about 20% to about 40%, and preferably about 30%.

Preferably, the resist composition does not comprise a photo acid generator.

In some embodiments, the resist composition does not comprise a peroxide group.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and a radiation source which may be used to irradiate the resist compositions of the present invention;

FIG. 2 depicts a schematic depiction of multivalency;

FIG. 3 depicts a schematic representation of the conversion mechanism of the resist composition according to a first embodiment of the present invention;

FIG. 4 depicts a schematic representation of the conversion mechanism of a resist composition according to a second embodiment of the present invention.

### DETAILED DESCRIPTION

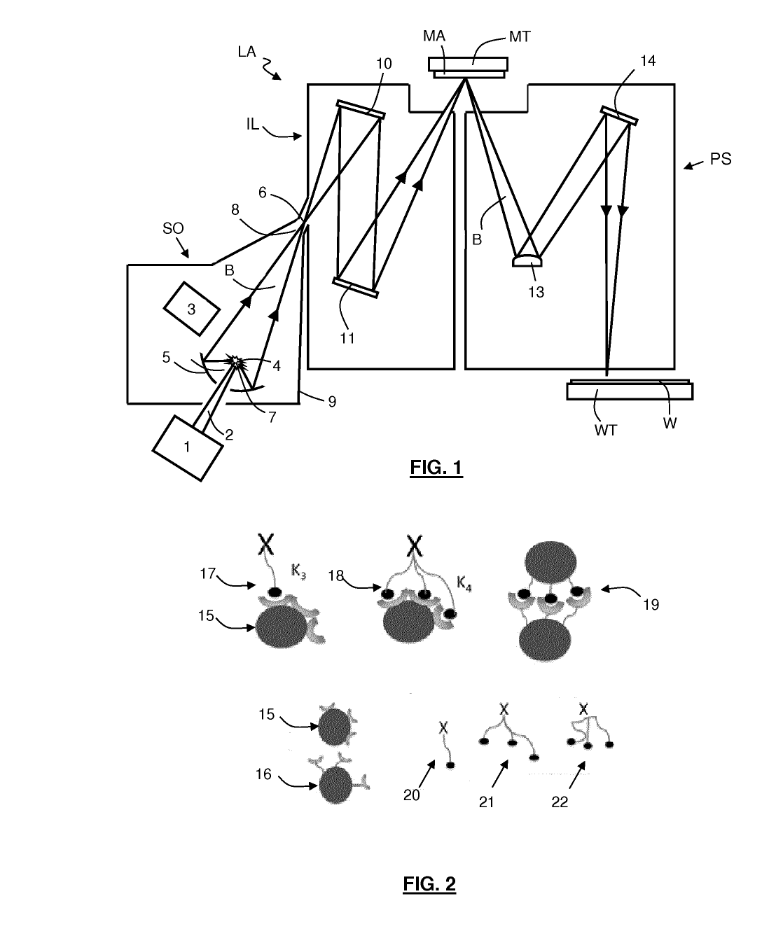

FIG. 1 shows a lithographic system which may be used to irradiate the resist compositions of the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. A layer of the resist composition according to an embodiment of the present invention is provided on the substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source). A laser 1, which may for example be a CO₂ laser, is arranged to deposit energy via a laser beam 2 into a fuel, such as tin (Sn) which is provided from a fuel emitter 3. Although tin is referred to in the following description, any suitable fuel may be used. The fuel may for example be in liquid form, and may for example be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a plasma 7 at the plasma formation region 4. Radiation, including EUV radiation, is emitted from the plasma 7 during de-excitation and recombination of ions of the plasma.

The EUV radiation is collected and focused by a near normal incidence radiation collector 5 (sometimes referred to more generally as a normal incidence radiation collector). The collector 5 may have a multilayer structure which is arranged to reflect EUV radiation (e.g. EUV radiation having a desired wavelength such as 13.5 nm). The collector 5 may have an elliptical configuration, having two ellipse focal points. A first focal point may be at the plasma formation region 4, and a second focal point may be at an intermediate focus 6, as discussed below.

The laser 1 may be separated from the radiation source SO. Where this is the case, the laser beam 2 may be passed from the laser 1 to the radiation source SO with the aid of a beam delivery system (not shown) comprising, for example, suitable directing mirrors and/or a beam expander, and/or other optics. The laser 1 and the radiation source SO may together be considered to be a radiation system.

Radiation that is reflected by the collector 5 forms a radiation beam B. The radiation beam B is focused at point 6 to form an image of the plasma formation region 4, which acts as a virtual radiation source for the illumination system IL. The point 6 at which the radiation beam B is focused may be referred to as the intermediate focus. The radiation source SO is arranged such that the intermediate focus 6 is located at or near to an opening 8 in an enclosing structure 9 of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

The term “EUV radiation” may be considered to encompass electromagnetic radiation having a wavelength within the range of 4-20 nm, for example within the range of 13-14 nm. EUV radiation may have a wavelength of less than 10 nm, for example within the range of 4-10 nm such as 6.7 nm or 6.8 nm.

Although FIG. 1 depicts the radiation source SO as a laser produced plasma LPP source, any suitable source may be used to generate EUV radiation. For example, EUV emitting plasma may be produced by using an electrical discharge to convert fuel (e.g. tin) to a plasma state. A radiation source of this type may be referred to as a discharge produced plasma (DPP) source. The electrical discharge may be generated by a power supply which may form part of the radiation source or may be a separate entity that is connected via an electrical connection to the radiation source SO.

Non-covalent bonding between molecules or nanoparticles with suitable groups (host and guest) can be described by the thermodynamic equilibrium constant K. A system in which there is a reversible reaction reaches an equilibrium in which the rate of one reaction equals the rate of the reverse reaction. Equation 1 below shows the reversible reaction between host (H) and guest (G) sites to form a compound in which the host and guest sites are bonded:

[H]+[G] [symbol] [HG] Equation 1:

The thermodynamic equilibrium constant of a reversible reaction is calculated Equation 2:

$$K = \frac{[ HG ]}{[ H ] [ G ]} \qquad Equation 2$$

In an equilibrium system, the host-guest system is continuously subjected to binding and de-binding events. In cases where K is large, the majority of the population will be in the bound state. In contrast, where K is small, the majority of the population will be in the unbound state. The driving force for host-guest binding may be considered as the overall reduction in Gibbs free energy (ΔG).

The Gibbs free energy comprises two contributions; i) enthalpy (ΔH) and ii) entropy (ΔS) and are connected via Equation 3:

ΔG=ΔH−TΔS, wherein T is temperature in Kelvin Equation 3:

It can be seen that an increase in the enthalpy of a reaction (in which an exothermic reaction is given a negative number) can offset a decrease in entropy, and vice versa.

The bonding between host and guest sites may be cooperative. Cooperative binding may be positive or negative. This means that binding of a host with multiple guests can result in an overall much larger or smaller binding constant than can be expected upon additive interactions only. For example, in cases of positive cooperativity, the equilibrium constant of a molecule having, for example, three guest sites, binding with three monodentate molecules is greater than three times the equilibrium constant of two monodentate molecules reversibly forming a guest-host bond with one another.

Larger thermodynamic equilibrium binding constants can be obtained in multivalent systems compared to positive cooperative systems.

Multivalency may be defined as an interaction between two or more multivalent agents, which comprises multiple independent interactions of the same type.

FIG. 2 shows a schematic illustration of a multivalent system. The main difference between multivalent systems and cooperative systems is that in multivalent systems, the molecules each have multiple host sites or multiple guest sites. Thus, multiple bonds may be formed between the molecules having the multiple guest sites and those having multiple host sites. It is of course possible for a molecule or nanoparticle to have both host and guest sites.

In FIG. 2, the thermodynamic equilibrium binding constant K4 is more than three times the thermodynamic equilibrium binding constant K3 of the system in which one of the molecules is monovalent. Thus, it is thermodynamically more favourable for the system to maximise host-guest interactions than for the host and guest sites to be unbonded.

The nanoparticle generally indicated as 15 depicts the nanoparticle having host sites on the surface of the nanoparticle. The nanoparticle generally indicated as 16 depicts the nanoparticle having molecules attached to the nanoparticles and the molecules having host end groups. The monovalent bond 17 between a molecule 20 having a single guest group and one of the host sites of nanoparticle 15 has a thermodynamic binding constant K3. Multivalent bonds 18, 19 between a multivalent molecule and nanoparticle 15, and between two nanoparticles respectively, have a thermodynamic binding constant K4. Since the bonds 18, 19 are multivalent, the thermodynamic binding constant K4 is more than three times the thermodynamic binding constant of the monovalent bond 17. The multivalent ligands 21, 22 show that the host groups may all be attached to a common element X, which may be a nanoparticle, directly, or one or more of the host groups may be linked indirectly to a common element X indirectly.

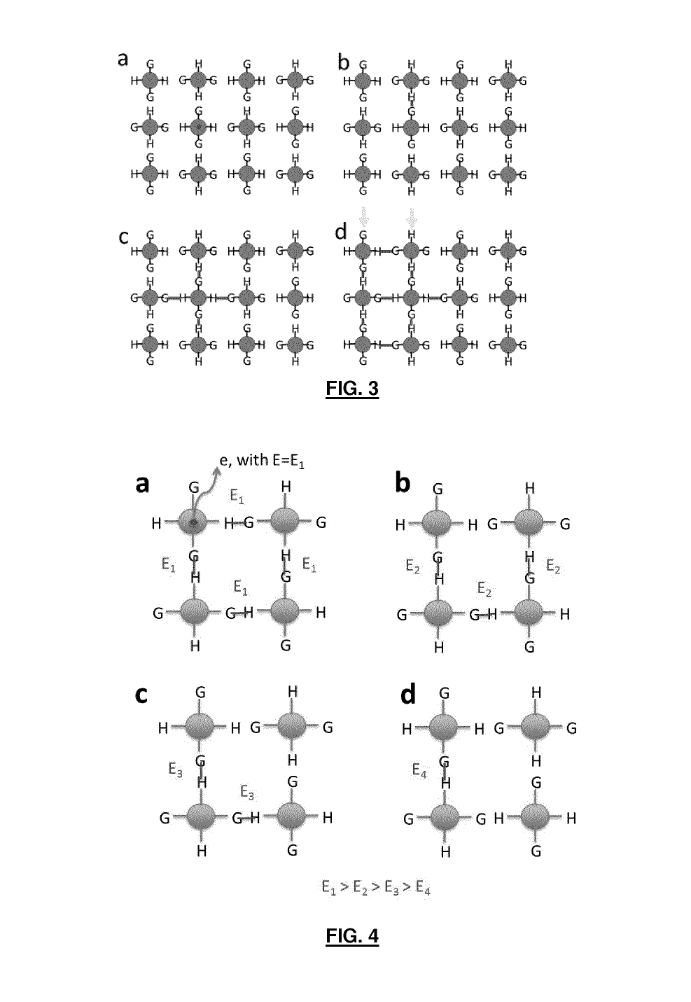

FIG. 3 is a schematic depiction of a resist composition according to the first embodiment of the present invention. FIG. 3a shows a matrix of metal oxide nanoparticles each surrounded by a shell of multivalent ligands. It will of course be appreciated that the guest and host sites may be present on the nanoparticles themselves or on ligands associated with the nanoparticles or covalently bonded linkers to nanoparticles equipped with host and or guest groups, or a combination of the three. The multivalent ligands have multiple guest sites and/or host sites. Upon irradiation with electromagnetic radiation, such as EUV, a photon is absorbed by the metal-containing nanoparticle which generates a secondary electron. The secondary electron can provide the energy required to form a bond between a guest site on a ligand associated with a first nanoparticle or on the nanoparticle itself, and a host site on a ligand associated with a second nanoparticle or on the second nanoparticle itself.

FIG. 3b shows a new bond formed between a guest site and a host site on adjacent particles. Since the ligands and/or nanoparticles are multivalent, the formation of the first bond makes the bond formation of the other host and/or guest sites on the nanoparticles or the ligands energetically more favourable. Thus, the secondary electrons generated after a nanoparticle absorbs a photon are more likely to form bonds involving such nanoparticle. In this way, the amount of blur caused by the diffusion of electrons is reduced.

FIG. 3c shows new bonds preferentially forming between neighbouring particles. In the first embodiment of the present invention, the most energetically favourable state is the one in which the bonding between the multivalent ligands and/or nanoparticles is maximised.

FIG. 3d shows schematically that the bonding between nanoparticles occurs preferentially in the area of the resist composition which is exposed to the electromagnetic radiation or electron beam.

FIG. 4 shows a second aspect of the present invention which is still based on multivalency, but is based on the breaking of host-guest bonds rather than the formation of host-guest bonds. The resist composition comprises nanoparticles, preferably comprising tin oxide, having a shell of multivalent ligands having guest and/or host sites. This system is soluble in a developer which contains monovalent ligands with guest and/or host sites that compete with the multivalent ligands. The monovalent ligands can bind to the ligands surrounding the nanoparticles thereby separating the ligands from the nanoparticles.

It is thermodynamically favourable to maximise host-guest interactions. Multivalent systems, such as those of the second embodiment of the present invention, generally maximise host-guest interactions by sacrificing the conformational degrees of freedom of the shape of the linkers available. The linkers may be any suitable group, but may be carbohydrates. The thermodynamic favourability of maximising host-guest bonds means that the host-guest system is normally firmly bonded. The bonding of the host-guest sites creates a matrix comprising the nanoparticles and the ligands. The interaction between the backbone of the ligands and the surrounding solvent will be minimised to allow the thermodynamically more favourable host-guest bonds to form, even at the expense of an increase in entropy. For example, a carbohydrate chain may curl up in order to allow host-guest bonding to occur since this results in an overall reduction in Gibbs free energy. Upon EUV exposure, secondary electrons break host-guest bonds. This causes the secondary electron to lose energy. Since the system is based on multivalency, the breaking of the first bond makes it energetically more favourable to break the remaining bonds associated with the nanoparticle. Thus, the secondary electron which has broken the first bond and is now of lower energy does not have sufficient to break one of the bonds of a fully-bonded nanoparticle, but has sufficient energy to break one of the bonds of a nanoparticle which has already had a bond broken. Thus, the multivalency of the system controls the reactions caused by secondary electrons and makes it more likely that photon absorption will result in cleavage of the host-guest bonds associated with the nanoparticle which absorbed the photon. Since the maximization of the host-guest bonding resulted in the minimisation of the interaction between the backbone of the ligand and the surrounding solvent by causing the backbone to curl up, the nanoparticles were brought into close proximity with each other and thus when the host-guest bonds are broken, in the regions exposed to the electromagnetic radiation or electron beam, the metal-containing nanoparticles will preferentially cluster in this region thereby making the areas insoluble in the developer. Aggregation of nanoparticles in this system is inhibited when the guest-host bonds between the ligands and/or the nanoparticles are in place. Thus, when the guest-host bonds are broken, this allows the nanoparticles to aggregate. The aggregated nanoparticles are insoluble in the developer and thus can be used as a negative resist. In the case of a positive resist composition which is based on the breakage of host-guest bonds, the breakage of the bonds preferably makes the resist composition more soluble in a developer.

Binding interaction between ligands, ligands and nanoparticles and/or nanoparticles may be tuned according to the specific desired composition. For example, it might be desired for use in a negative resist that high binding constants are obtained when forming multivalent binding. For use in a positive resist, such a system may be designed with weaker binding constants in order to allow monovalent ligands to compete for the binding sites hereby dissembling the host-guest groups between nanoparticles, ligands on nanoparticles or on linkers covalently bonded to nanoparticles.

The resist compositions of the first and second embodiments of the present invention may be used in methods for producing semiconductor devices.

The resist composition may be applied to a semiconductor substrate. The resist may then be exposed to electromagnetic radiation, such as EUV, or an electron beam. The resist may then be developed.

The method may comprise baking the semiconductor substrate. Without wishing to be limited by scientific theory, it is believed that electrons in the resist composition of the first embodiment of the present invention will be excited and will form further bonds. Since the ligands and/or nanoparticles, are multivalent, such bonds will preferentially form between ligands and/or nanoparticles which are already bonded. Thus, it is believed that baking will not significantly enhance blur. The method may be developed in any suitable developer. In accordance with the first embodiment of the present invention, the connected nanoparticles and ligands are insoluble in the developer and will remain on the surface of the semiconductor substrate after development. The nanoparticles which are not connected are soluble in the developer and are removed during development.

Alternatively, in accordance with the second embodiment of the present invention, which is based on breakage of bonds and the agglomeration of nanoparticles, during baking, the nanoparticles and/or ligands which are bonded multivalently to other nanoparticles and/or ligands, are in their most thermodynamically stable state and there is therefore a lower likelihood of the bonds breaking. In contrast, there is an increased likelihood of the bonds associated with the nanoparticles and/or ligands which have already had one or more bonds to other ligands and/or nanoparticles broken being broken. Thus, it is believed that baking will not significantly enhance blur. The nanoparticles which have been able to agglomerate due to breakage of the host-guest bonds are insoluble in the developer and remain on the surface of the semiconductor substrate after development. The area or areas of the resist composition which have not been exposed to electromagnetic radiation or an electron beam can be developed in a developer comprising high concentrations of monovalent ligands which compete for the host-guest interactions. Higher concentrations of monovalent ligands in the developer solution can be altered to tune solubility by replacing multivalent interactions with monovalent interactions. In this way, the occurrence of binding and debinding events of multivalent complexes is forced to the state where guest sites are occupied by monovalent ligands. Alternatively, where the resist composition is a positive resist, the area or areas of the resist exposed to the electromagnetic radiation of electron beam are soluble in the developer.

### Example 1—Negative Resist Composition Based on Bond Formation

The composition comprises an absorber part and a crosslinking part. The absorber part is a metal-containing nanoparticle and the crosslinking part is a multivalent ligand. In solution, the nanoparticles are mainly negatively charged. In this example the nanoparticles are SnOₓ nanoparticles, although any suitable nanoparticle may be used. The surface of the nanoparticles has a plurality of negatively charged host sites. A host site is a site which can form a bond with a guest site on another nanoparticle or ligand. Any suitable guest-host bond may be used. In the present example, the host-guest bonds are formed between the negatively charged host sites on the surface of the nanoparticles and positively charged guest sites on the ligands. The positively charged guest sites may comprise primary or secondary amines. The ligand may comprise a carbohydrate backbone with one or more primary or secondary amines attached. The ligand includes a plurality of guest sites. However, it will be appreciated that any suitable guest-host bond may be used. For example, an electron may cause a conformational change in the guest site which allows the bond to the host site to form. Such conformational change may be a transition between a cis-conformation and a trans-conformation and vice versa.

The creation of the host-guest bonds brings the nanoparticles into close proximity to one another. This may be a result of the at least partial disintegration of the carbohydrate chains to allow clustering. Secondary electrons generated by electromagnetic radiation or electron beam exposure may cause debinding of the positively charged guest sites. As a result of this, the nanoparticles are able to cluster together upon localised debinding of the ligands. In unexposed areas, the nanoparticles will not cluster as they are surrounded by ligands. The solubility of the unexposed areas and further clustering of the nanoparticles in exposed areas can be enhanced during development by applying a developer solution having a large concentration of monovalent ligands.

### Example 2—Negative Resist Composition Based on Bond Breakage

As with Example 1, the guest-host system is based on electrostatic interactions between the negatively charged host sites on the nanoparticles and the positively charged guest sites on the ligands. The ligands may comprise primary or secondary amine groups attached to a carbohydrate backbone. The electrons generated following exposure to electromagnetic radiation or an electron beam can caused debinding of the positively charged guest sites. The energy of the secondary electron is reduced by the breakage of the first bond and therefore it is preferred to break the guest-host bond on the same nanoparticle rather than on another nanoparticle which is fully bonded. This localises the debinding events and causes clustering of the nanoparticles. The ligands may comprise thermocleavable groups which may be broken when the resist is baked to further reduce solubility and force clustering. In addition, the solubility of unexposed areas may be enhanced by having a large concentration of monovalent host ligands in the developer solution.

### Example 3—Positive Resist Composition Based on Bond Breakage

In a similar way to Example 2, the generation of secondary electrons can lead to the breakage of host-guest bonds. Alternatively, the secondary electrons could break the ligand itself. In turn this would allow the unbonded areas to dissolve in a developer solution. Debinding of multivalent host-guest bonds in unexposed areas can be enhanced by using a developer solution with a high concentration of monovalent ligands. The ligands may comprise thermocleavable groups which may be broken when the resist is baked to further improve solubility.

Whilst specific embodiments of the invention have been described above, it will be appreciated that the invention may be practiced otherwise than as described. Whilst reference to nanoparticles has been made in the detailed description and examples, it is equally possible to use nanoclusters in the present invention. Similarly, whilst reference to ligands has been made in the detailed description and examples, it is equally possible to use organic linkers in the present invention.

The descriptions above are intended to be illustrative and not limiting. Thus, it will be apparent to one skilled in the art that modifications may be made to the invention as described without departing from the scope of the claims.

The present invention relies upon multivalency to control the secondary electrons generated when a resist composition is exposed to electromagnetic radiation, such as EUV, or an electron beam. The use of multivalent nanoparticles and/or nanoclusters, and ligands and/or organic linkers reduces the blur caused by the diffusion of secondary electrons and positions the nanoparticles and/or nanoclusters with respect to each other in a more controlled fashion. The present invention also balances the improved absorption cross-section of metal oxide nanoparticles and/or nanoclusters compared with carbon in known chemically amplified resists with the increase in the number of secondary electrons generated. The present invention allows for both positive and negative resists to be produced which have advantageous properties over known resists.

1. A resist composition comprising:
a) metal-containing nanoparticles and/or nanoclusters, and
b) ligands and/or organic linkers,
wherein one or both of a) or b) are multivalent.

2. The resist composition according to claim 1, wherein the resist composition is a negative resist or a positive resist.

3. The resist composition according to claim 1, wherein:
i) the resist composition is a negative resist and the nanoparticles and/or nanoclusters cluster upon crosslinking of the ligands and/or organic linkers following exposure to electromagnetic radiation or an electron beam; or
ii) the resist composition is a negative resist and the ligands and/or organic linkers are crosslinked and the crosslinking bonds are broken upon exposure to electromagnetic radiation or an electron beam allowing the nanoparticles and/or nanoclusters to cluster together; or
iii) the resist composition is a positive resist and the ligands and/or organic linkers are crosslinked and the crosslinking bonds are broken upon exposure to electromagnetic radiation or an electron beam.

4. The resist composition according to claim 1, wherein the metal-containing nanoparticles and/or nanoclusters are metal oxide nanoparticles and/or nanoclusters.

5. The resist composition according to claim 1, wherein the metal is selected from; one or more alkali metals, one or more alkali earth metals, one or more transition metals, one or more lanthanides, one or more actinides, or one or more post-transition metals.

6. The resist composition according to claim 1, wherein the metal oxide nanoparticles and/or nanoclusters comprise tin oxide and/or hafnium oxide.

7. The resist composition according to claim 1, wherein the total lateral dimension of the nanoparticles and/or nanoclusters is from about 0.1 nm to about 10 nm.

8. The resist composition according to claim 1, wherein the height of the nanoparticles and/or nanoclusters is from about 0.1 nm to about 10 nm.

9. The resist composition according to claim 1, wherein the metal-containing nanoparticles and/or nanoclusters comprise a plurality of guest sites, host sites, or both guest and host sites.

10. The resist composition according to claim 1, wherein the ligands and/or organic linkers comprise a plurality of guest sites, host sites, or both guest and host sites.

11. The resist composition according to claim 1, wherein the metal-containing nanoparticles, nanoclusters, ligands and/or organic linkers comprise a plurality of host sites and the host sites comprise one or more host groups selected from primary ammonium groups, secondary ammonium groups, tertiary ammonium groups, quaternary ammonium groups, amine oxides, carbocations, or peptides, and/or wherein the metal-containing nanoparticles, nanoclusters, ligands and/or organic linkers comprise a plurality of guest sites and the guest sites comprise one or more guest groups selected from DNA base pairs, peptides or charged surface areas of the nanoparticles and/or nanoclusters.

12. The resist composition according to claim 1, wherein the ligands and/or organic linkers comprise a linker portion.

13. The resist composition according to claim 1, wherein the ligands and/or organic linkers comprise one or more cleavable groups and/or one or more curable groups.

14. The resist composition according to claim 13, wherein the one or more cleavable groups is selected from esterquats, carbonate esters, peptides, carbamates, azulenes, spiropyrans, azobenzenes, viologens, amides, diselenides, disulfides, acetals, trithiocarbonates, carbonates, ketals, esters, ortho esters, imines, hydrazones, hemi acetal esters, olefins, thiol-enes, ketones, enols, photolabile groups, dienes, or alkenes.

15. The resist composition according to claim 1, wherein the solubility of the composition is altered following exposure to electromagnetic radiation or an electron beam.

16. The resist composition according to claim 1, wherein upon exposure to electromagnetic radiation or an electron beam, a bond is formed between a guest site on a first nanoparticle and/or nanocluster or on a ligand and/or organic linker surrounding a first nanoparticle and/or nanocluster, and a host site on a second nanoparticle and/or nanocluster or on a ligand and/or organic linker surrounding a second nanoparticle and/or nanocluster, wherein the formation of the bond makes it more energetically favourable to form bonds between the first and/or second nanoparticles and/or nanoclusters, or ligands and/or organic linkers surrounding the first and/or second nanoparticles and/or nanoclusters, with other nanoparticles and/or nanoclusters, and/or ligands and/or organic linkers.

17. The resist composition according to claim 16, wherein the formation of guest-host bonds between the ligands and/or organic linkers causes the nanoparticles and/or nanoclusters to cluster thereby reducing the solubility in a developer of the area exposed to the electromagnetic radiation or the electron beam.

18. The resist composition according to any claim 1, wherein guest sites on a first plurality of ligands and/or organic linkers, and host sites on a second plurality of ligands and/or organic linkers form a matrix of ligands and/or organic linkers held together by guest-host bonds, wherein upon exposure to electromagnetic radiation or an electron beam, the guest-host bonds are broken and the breaking of the guest-host bonds makes it energetically more favourable to break bonds between ligands and/or organic linkers surrounding the metal-containing nanoparticles and/or nanoclusters associated with the ligands and/or organic linkers whose guest-host bonds have been broken than other nanoparticles and/or nanoclusters whose associated ligands and/or organic linkers have not had their guest-host bonds broken.

19. The resist composition according to claim 18, wherein the breakage of guest-host bonds between the ligands and/or organic linkers alters the solubility of the areas where the bond breakage occurs in a developer.

20. A method of producing a semiconductor, the method comprising:
applying to a semiconductor substrate a resist composition comprising:
a) metal-containing nanoparticles and/or nanoclusters, and
b) ligands and/or organic linkers,
wherein one or both of a) or b) are multivalent;
exposing the resist to electromagnetic radiation or an electron beam; and
developing the resist.

21.-23. (canceled)
